(19) United States
(12) Patent Application Publication
(10) Pub. No.: US 2013/0284505 A1
(43) Pub. Date: Oct. 31, 2013

(54) ADHESIVE MEMBER FOR MANUFACTURING PRINTED CIRCUIT BOARD, PRINTED CIRCUIT BOARD, AND METHOD OF MANUFACTURING THE SAME

(71) Applicant: SAMSUNG ELECTRO-MECHANICS CO., LTD., Suwon (KR)

(72) Inventors: Kee Su JEON, Suwon (KR); Choon Keun LEE, Suwon (KR); Ji Hye SHIM, Suwon (KR)

(21) Appl. No.: 13/871,780

(22) Filed: Apr. 26, 2013

(30) Foreign Application Priority Data
Apr. 26, 2012 (KR) 10-2012-0043848

(51) Int. Cl. H05K 3/46; H05K 1/09; B32B 7/12; H05K 1/03

(52) U.S. Cl. CPC H05K 3/4644; H05K 1/0306; H05K 1/09; B32B 7/12
USPC 174/257; 427/97.1; 156/237; 174/250; 174/258; 174/256; 428/343; 428/354

(57) ABSTRACT

Disclosed herein are an adhesive member for manufacturing a printed circuit board, a printed circuit board, and a method of manufacturing the same. The printed circuit board includes a base substrate, an insulating layer formed on the base substrate, a primer layer formed on the insulating layer, and a circuit layer formed on the primer layer.

### CROSS REFERENCE TO RELATED APPLICATION

This application claims the benefit of Korean Patent Application No. 10-2012-0043848, filed on Apr. 26, 2012, entitled “Adhesive Member for Manufacturing Printed Circuit Board, Printed Circuit Board and Method of Manufacturing the Same”, which is hereby incorporated by reference in its entirety into this application.

### BACKGROUND OF THE INVENTION

1. Technical Field

The present invention relates to an adhesive member for manufacturing a printed circuit board, a printed circuit board, and a method of manufacturing the same.

2. Description of the Related Art

The development of electronic device technologies and demand for various functions has prompted electronic devices to have high performance, high integration, a small size, and the like. Thus, a printed circuit board (PCB) for mounting various electronic components thereon is required to be highly integrated and reduced in size, and in line with this, circuits are designed to be increasingly smaller.

Meanwhile, PCBs having various structures including Document 1 employ a method of forming roughness on a surface of an insulating layer to enhance a bonding force between an insulating layer and a metal layer, and here, as the roughness is increased, the bonding force between the insulating layer and the metal layer is enhanced.

However, in the process of fabricating a PCB, it is commonly known that the PCB is partially etched to form circuits after performing metal plating, and in this case, etching is not completely performed due to a rough surface. Here, a remnant metal material causes a defective contact between circuits.

Also, the structure in which a contact surface between the insulating layer and the metal layer due to roughness may act as resistance while a current flows, which may cause a signal loss. The probability of occurrence of the foregoing phenomenon is increased as the circuit patterns of the PCB become finer.

### PRIOR ART DOCUMENT

### Patent Document

(Patent Document 1) [Document 1] U.S. 2006/0191709 A. 2006. 8. 31

### SUMMARY OF THE INVENTION

The present invention has been made in an effort to provide an adhesive member for manufacturing a printed circuit board (PCB) having one surface with enhanced adhesive strength with a metal although a process of forming roughness on a surface of an insulating layer is omitted, a printed circuit board, and a method of manufacturing the same.

According to one preferred embodiment of the present invention, there is provided a printed circuit board (PCB) including: a base substrate; an insulating layer formed on the base substrate; a primer layer formed on the insulating layer; a surface treatment layer formed on the primer layer; and a circuit layer formed on the surface treatment layer.

The primer layer may be made of an epoxy resin or a polymer including an epoxy group.

The primer layer may include a binder including a functional group reacting to the epoxy.

The epoxy resin may be a DGEBA (diglycidyl ether of bisphenol A)-based epoxy resin or a novolac epoxy resin.

The polymer may be poly glycidyl methacrylate.

The primer layer may be formed to have a thickness of 0.5% to 5% of the thickness of the insulating layer.

A roughness value (Ra) of the primer layer with the surface treatment layer formed thereon may be 50 nm or less.

The surface treatment layer may be made of a compound including a mercapto group, a disulfide group, or a triazole group.

The base substrate may be a copper-clad lamination plate.

According to another preferred embodiment of the present invention, there is provided an adhesive member for manufacturing a printed circuit board, the adhesive member including: a carrier film; and a primer layer formed on the carrier film.

The primer layer may be made of an epoxy resin or a polymer including an epoxy group.

The adhesive member may further include: an insulating layer formed on the primer layer.

The primer layer may be formed to have a thickness of 0.5% to 5% of the thickness of the insulating layer.

The adhesive member may further include: a surface treatment layer formed between the primer layer and the carrier film.

A roughness value (Ra) of the primer layer with the surface treatment layer formed thereon may be 50 nm or less.

The surface treatment layer may be made of a compound including a mercapto group, a disulfide group, or a triazole group.

According to another preferred embodiment of the present invention, there is provided a method of manufacturing a printed circuit board (PCB), including: preparing a base substrate; forming an insulating layer on the base substrate; forming a primer layer on the insulating layer; forming a surface treatment layer on the primer layer; and forming a circuit layer on the surface treatment layer.

The forming of the primer layer may include: preparing a carrier film; forming an adhesive member by transferring the primer layer onto the carrier film; disposing the adhesive member such that the primer layer is in contact with the insulating layer; bonding the insulating layer and the primer layer through a pre-curing process; and removing the carrier film.

The method may further include: performing post-curing process, after the forming of the circuit layer.

In the forming of the primer layer, the primer layer may be formed to have a thickness of 0.5% to 5% of the thickness of the insulating layer.

A roughness value (Ra) of the primer layer with the surface treatment layer formed thereon may be 50 nm or less.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a configuration of a printed circuit board (PCB) according to an embodiment of the present invention;

FIGS. 2 through 6 are cross-sectional views showing a sequential process of a method of manufacturing the PCB of FIG. 1;

FIG. 7 is a cross-sectional view showing a first embodiment of an adhesive member for manufacturing a PCB according to the present invention;

FIG. 8 is a cross-sectional view showing a second embodiment of an adhesive member for manufacturing a PCB according to the present invention;

FIG. 9 is a graph showing a change in a thermal expansion coefficient over a ratio of a thickness of a primer layer to that of an insulating layer according to an embodiment of the present invention; and

FIG. 10 is a graph showing roughness values of the primer layer having a surface treatment layer formed thereon according to an embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Printed Circuit Board

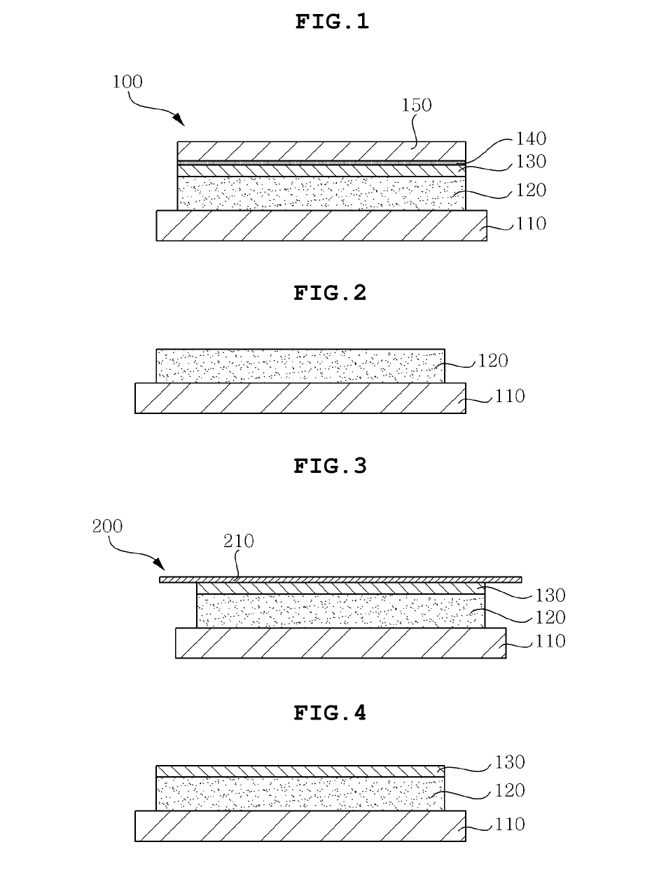

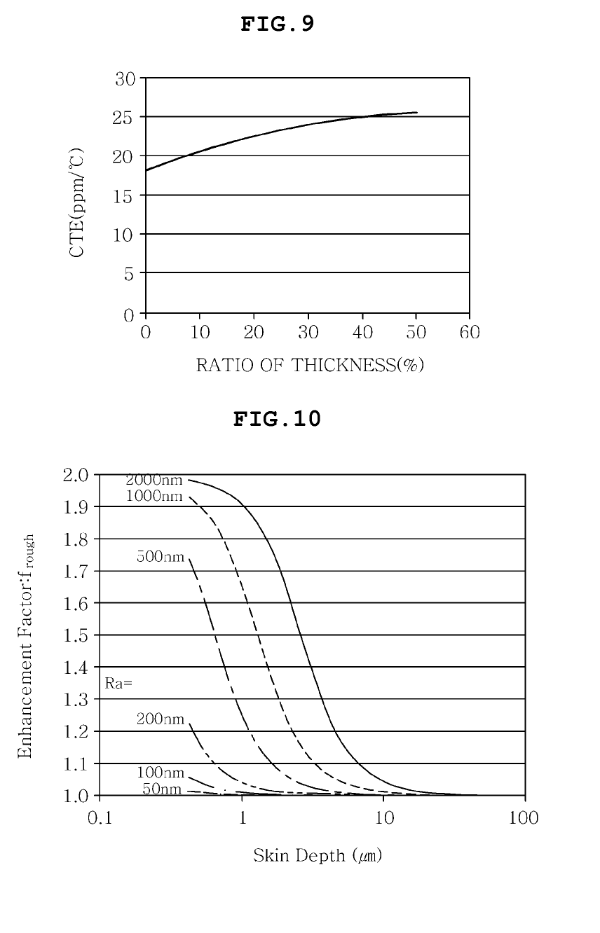

FIG. 1 is a cross-sectional view showing a configuration of a printed circuit board (PCB) according to an embodiment of the present invention. The configuration of the PCB according to an embodiment of the present invention will be described with reference to FIG. 9 that shows a graph showing a change in a thermal expansion coefficient in respects to a ratio of a thickness of a primer layer to an insulating layer according to an embodiment of the present invention and FIG. 10 that shows a graph showing roughness values of the primer layer having a surface treatment layer formed thereon according to an embodiment of the present invention.

As shown in FIG. 1, a PCB 100 may include a base substrate 110, an insulating layer 120 formed on the base substrate 110, a primer layer 130 formed on the insulating layer 120, a surface treatment layer 140 formed on the primer layer 130, and a circuit layer 150 formed on the surface treatment layer 140.

Here, the primer layer 130 may be made of an epoxy resin or a polymer including an epoxy group.

Also, the epoxy resin may be a DGEBA (diglycidyl ether of bisphenol A)-based epoxy resin or a novolac epoxy resin.

Also, the polymer may be poly glycidyl methacrylate.

The epoxy resin according to an embodiment of the present invention refers to an epoxy resin in which two or more epoxy groups are included in a molecule, and a type thereof is not limited as long as it can be used as an electronic electric material.

For example, as the epoxy resin, a compound including short chains, such as a DGEBA (diglycidyl ether of bisphenol A) epoxy resin, a novolac epoxy resin, or the like, may be used, or a polymer may be used. Preferably, the polymer is poly glycidyl methacrylate (PGMA) in a sense that it is easily synthesized and an ester group helps an adhesive strength with a metal. When the polymer is used, a molecular weight may range from 5,000 to 30,000.

Also, PGMA is represented by Chemical Formula 1 shown below.

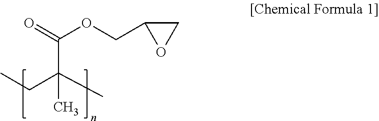

Here, n may be 35 to 210.

Also, the primer layer 130 may further include a binder including a functional group reacting to an epoxy group.

The binder, which is used to enhance film characteristics of the primer layer 130 and stabilizes the primer film, may be an oligomer or a polymer and is not limited in the length and type of chains thereof.

Also, the binder may include a functional group that may react to an epoxy group, and two or more functional groups may be included in a single binder.

For example, the functional group that may react to epoxy may include an amine group, an alcohol group, a carboxyl group, and the like.

Also, the primer layer 130 may have a thickness of 0.5% to 5% of the thickness of the insulating layer 120. Here, the insulating layer 120 may be an epoxy resin composition.

The foregoing thickness of the primer layer 130 is considered such that the primer layer 130 without a filler does not cause deformation of physical qualities of the insulating layer 120 including large amounts of filler.

For example, as illustrated in FIG. 9, it can be seen that, when the primer layer 130 according to an embodiment of the present invention is within the thickness range of 0.5% to 5% of the thickness of the insulating layer 120, a variation of a coefficient of thermal expansion (CTE) is less than 10% based on a reference CTE of 17 ppm/° C. Here, the reference CTE is based on a CTE of copper commonly used as a material of the circuit layer 150.

In comparison, when the thickness of the primer layer 130 exceeds the thickness range of 0.5% to 5% of the thickness of the insulating layer 120, it exceeds the allowable variation of 10% of the reference CTE of 17 ppm/° C. such that it is not appropriate to use the primer layer 130 as an element of the PCB.

Namely, when the primer layer 130 has a thickness less than 0.5% of the thickness of the insulating layer 120, it has difficulty in forming the primer layer on the insulating layer 120, and when the thickness of the primer layer 130 exceeds 5% of the thickness of the insulating layer 120, the primer layer 130 would affect the physical properties of the insulating layer 120.

Also, a roughness value Ra of the primer layer 130 on which the surface treatment layer 140 is formed may be 50 nm or less.

Here, the roughness value Ra indicates roughness, which is an average value obtained by averaging absolute values of heights based on an average height. In an embodiment of the present invention, the roughness value Ra was measured within a measurement range of 170 μm×226 μm by a 50-fold interference lens by using NVM-5161P made by Nano System Co., Ltd.

For example, an attenuation constant a of a signal may be expressed by α=f_{rough}α_{c}+α_{d}. Here, α_{c} is a loss made by a conductor, and α_{d} is a loss made by a dissipation factor and both the two values are based on a flat interface. Roughness of the insulating layer 120 and the circuit layer 150 is reflected on an enhancement factor f_{rough}, which may be represented by Equation 1 shown below.

$${f}_{rough} = 1 + \frac{2}{π} arctan [ 1.4 {( Rq / d )}^{2} ] \qquad [ Equation 1 ]$$

Here, Rq is a root mean square, which is calculated to be 1.1 times Ra, and d is a skin depth.

As a frequency is increased, a skin depth is reduced. As shown in FIG. 10, it can be seen that, when roughness Ra is 50 nm, the enhancement factor f_{rough} is close to 1 in a high frequency region, and as roughness Ra is increased (e.g., Ra=100 nm, Ra=200 nm, Ra=500 nm, . . . ), the enhancement factor f_{rough} is correspondingly increased in the high frequency region.

The surface treatment layer 140 according to an embodiment of the present invention is defined to be a layer formed by treating a surface of the primer layer 130 with a compound having excellent adhesive strength with a metal (e.g., copper) in order to enhance adhesive strength between a metal thin film for a formation of the circuit layer 150 and the primer layer 130.

Here, the surface treatment layer 140 may be made of a compound including a mercapto group, a disulfide group, or a triazole group.

For example, the compound may be a 4-aminothiophenol, 4-aminophenyl disulfide, benzotriazole-5-carboxylic acid, 5-(4-Aminophenyl)-1,3,4-oxadiazole-2-thiol, pentaerythritol tetrakis(3-mercaptopropionate), or the like.

Also, the base substrate 110 may be a copper-clad lamination plate.

Also, the insulating layer 120 may include an epoxy resin, a hardener (or a curing agent), an inorganic filler, and any other additives, but, without being limited thereto, any component including a composite epoxy resin may be used.

In the PCB according to an embodiment of the present invention, although a process of forming roughness on the surface of the insulating layer 120 is omitted, the adhesive strength with the metal layer can be enhanced. Thus, a flat contact surface can be formed between the insulating layer 120 and the metal layer, and thus, an occurrence of a phenomenon such as a defective contact (i.e., short) or a signal loss otherwise caused by a remnant metal material according to an increase in roughness can be prevented.

Also, in the PCB according to an embodiment of the present invention, roughness is not formed on the surface of the insulating layer 120, and thus, a circuit pattern of the PCB can be formed finer.

Also, since the primer layer 130 having a smaller thickness than that of other elements is applied to enhance adhesive strength between the insulating layer and the metal layer, the adhesive strength between the insulating layer and the metal layer can be enhanced while maintaining the physical properties of the insulating layer.

Method of Manufacturing PCB

FIGS. 2 through 6 are cross-sectional views showing a sequential process of a method of manufacturing the PCB of FIG. 1. This will be described with reference to FIGS. 7 and 8 as sectional views showing first and second embodiments of an adhesive member for manufacturing a PCB.

First, as illustrated in FIG. 2, the base substrate 110 may be prepared, and the insulating layer 120 may be formed on the base substrate 110.

Here, the base substrate 110 may be a copper-clad lamination plate, and the insulating layer 120 may be made of an epoxy resin composition.

The insulating layer 120 may be formed by performing a process of applying an epoxy resin composition to the base substrate 110 by using vacuum lamination, removing a carrier film for the insulating layer 120, and then, performing drying in a convection oven. However, the present invention is not limited thereto and the insulating layer 12 may be formed on the base substrate 110 through various processes. Such processes aim at removing a remnant solvent.

Next, as shown in FIGS. 3 and 4, the primer layer 130 may be formed on the insulating layer 120.

In detail, with reference to FIGS. 3, 4, and 7, a step of forming the primer layer 130 may include a step of preparing a carrier film 210 and a step of transferring the primer layer 130 onto the carrier film 210 to form an adhesive member 200.

Also, the step of forming the primer layer 130 may include a step of disposing the adhesive member 200 such that the primer layer 130 is in contact with the insulating layer 120, a step of bonding the insulating layer 120 and the primer layer 130 through a pre-curing process, and a step of removing the carrier film 210.

The primer layer 130 may be formed to have a thickness of 0.5% to 5% of the thickness of the insulating layer 110.

Also, the carrier film 210 may be PET (poly ethylene terephthalate), but without being limited thereto, any materials may be used so long as they have a glass transition temperature (Tg) higher than a fabrication process temperature, are not dissolved in a solvent for the primer layer 130, and do not have such high adhesive strength with the primer layer 130 as to completely transfer the primer layer 130 onto the insulating layer 120.

Also, the primer layer 130 transferred onto the carrier film 210 may include a binder for enhancing film characteristics of the primer layer 130 and stabilizing the primer film.

Also, as the process for forming the primer layer 130 on the carrier film 210, a gravure printing process, a slot die process, or the like, may be applied.

Also, in the step of bonding the insulating layer 120 and the primer layer 130 through a pre-curing process, the epoxy group of the primer layer 130 reacts to a hardener (or a curing agent) of the insulating layer 120 to chemically bond the two layers.

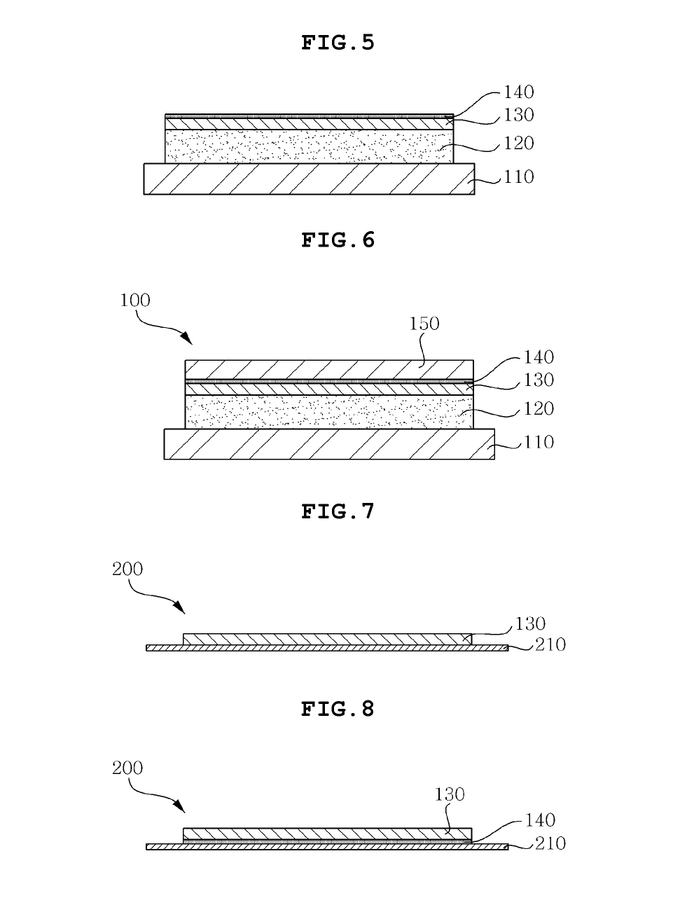

And then, as shown in FIG. 5, the surface treatment layer 140 may be formed on the primer layer 130.

Here, the surface treatment layer 140 according to an embodiment of the present invention is defined to be a layer formed by treating a surface of the primer layer 130 with a compound having excellent adhesive strength with a metal (e.g., copper) in order to enhance adhesive strength between a metal thin film for a formation of the circuit layer 150 and the primer layer 130.

The surface treatment layer 140 may bond compounds through a reaction with an epoxy group remaining after a reaction with a functional group of the binder included in the primer layer 130.

Here, the reaction with the epoxy group of the surface treatment layer may be made at room temperature or through heat.

The surface treatment layer 140 is bonded with the primer layer 130 according to a chemical reaction between the compound of the surface treatment layer 140 and the epoxy of the primer layer 130. Thus, after performing a cleaning operation, the compound forms a single layer on the primer layer 130, and thus, it can be formed to be thin enough not to affect the thickness of the section of the primer layer 130.

Here, the surface treatment layer 140 may be formed through a dipping method, a spray coating method, a bar coater method, a blade method, a brush painting method, or the like, but the present invention is not limited thereto.

Meanwhile, the method of forming the surface treatment layer 140 on the primer layer 130 through a chemical treatment may be replaced by a plasma processing method, a method of processing the surface of the primer layer 130 by using a photocatalyst such as TiO₂.

A roughness value (Ra) of the primer layer 130 with the surface treatment layer 140 formed thereon may be 50 nm or less.

Thereafter, as shown in FIG. 6, the circuit layer 150 may be formed on the surface treatment layer 140.

The circuit layer 150 may be formed on the surface treatment layer 140 by forming a metal layer for a formation of a circuit layer through electroless plating and electrodeposition, and then, performing a patterning process.

Here, as the patterning process, a subtractive method or a semi-additive method may be applied, but the present invention is not limited thereto.

After performing plating, a post-curing process may be performed on the PCB 100.

Here, through the post-curing process performed after performing a plating process on the surface treatment layer 140, adhesive strength can be enhanced and the metal foil can be stabilized.

Adhesive Member for Manufacturing PCB

FIG. 7 is a cross-sectional view showing a first embodiment of the adhesive member for manufacturing a PCB according to the present invention, and FIG. 8 is a cross-sectional view showing a second embodiment of the adhesive member for manufacturing a PCB according to the present invention.

Hereinafter, the adhesive member for manufacturing a PCB refers to an element as one of the elements of the PCB, which is formed on a separate carrier film The adhesive member may be bonded with a different element of the PCB, and after the bonding, the carrier film may be removed.

As shown in FIG. 7, the adhesive member 200 for manufacturing a PCB may include the carrier film 210 and the primer layer 130 formed on the carrier film 210.

The carrier film 210 may be PET (poly ethylene terephthalate), but without being limited thereto, any materials may be used so long as they have a glass transition temperature (Tg) higher than a fabrication process temperature, are not dissolved in a solvent for the primer layer 130, and do not have such high adhesive strength with the primer layer 130 as to completely transfer the primer layer 130 onto the insulating layer 120.

Also, the primer layer 130 may be made of an epoxy resin or a polymer including an epoxy group. Although not shown, the adhesive member 200 for manufacturing a PCB may further include the insulating layer 120 formed on the primer layer 130.

The primer layer 130 may be formed to have a thickness of 0.5% to 5% of the thickness of the insulating layer 120.

Meanwhile, as shown in FIG. 8, the adhesive member 200 for manufacturing a PCB may further include the surface treatment layer 140 formed between the primer layer 130 and the carrier film 210.

Also, a roughness value (Ra) of the primer layer 130 with the surface treatment layer 140 formed thereon may be 50 nm or less.

Here, the surface treatment layer 140 may be made of a compound including a mercapto group, a disulfide group, or a triazole group.

In the adhesive member for manufacturing a PCB, the PCB, and the method of manufacturing the same according to the preferred embodiments of the present invention, although a process of forming roughness on the surface of the insulating layer 120, adhesive strength with the metal layer can be enhanced. Thus, a flat contact surface can be formed between the insulating layer 120 and the metal layer, and thus, an occurrence of a phenomenon such as a defective contact (i.e., short) or a signal loss otherwise caused by a remnant metal material according to an increase in roughness can be prevented.

Also, since the primer layer having a smaller thickness than that of other elements is applied to enhance adhesive strength between the insulating layer and the metal layer, the adhesive strength between the insulating layer and the metal layer can be enhanced while maintaining the physical properties of the insulating layer.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board (PCB) comprising:
a base substrate;
an insulating layer formed on the base substrate;
a primer layer formed on the insulating layer;
a surface treatment layer formed on the primer layer; and
a circuit layer formed on the surface treatment layer.

2. The PCB as set forth in claim 1, wherein the primer layer is made of an epoxy resin or a polymer including an epoxy group.

3. The PCB as set forth in claim 2, wherein the primer layer includes a binder including a functional group reacting to the epoxy.

4. The PCB as set forth in claim 2, wherein the epoxy resin is a DGEBA (diglycidyl ether of bisphenol A)-based epoxy resin or a novolac epoxy resin.

5. The PCB as set forth in claim 2, wherein the polymer is poly glycidyl methacrylate.

6. The PCB as set forth in claim 1, wherein the primer layer is formed to have a thickness of 0.5% to 5% of the thickness of the insulating layer.

7. The PCB as set forth in claim 1, wherein a roughness value (Ra) of the primer layer with the surface treatment layer formed thereon is 50 nm or less.

8. The PCB as set forth in claim 1, wherein the surface treatment layer is made of a compound including a mercapto group, a disulfide group, or a triazole group.

9. The PCB as set forth in claim 1, wherein the base substrate is a copper-clad lamination plate.

10. An adhesive member for manufacturing a printed circuit board, the adhesive member comprising:
a carrier film; and
a primer layer formed on the carrier film

11. The adhesive member as set forth in claim 10, wherein the primer layer is made of an epoxy resin or a polymer including an epoxy group.

12. The adhesive member as set forth in claim 10, further comprising:
an insulating layer formed on the primer layer.

13. The adhesive member as set forth in claim 12, wherein the primer layer is formed to have a thickness of 0.5% to 5% of the thickness of the insulating layer.

14. The adhesive member as set forth in claim 10, further comprising:
a surface treatment layer formed between the primer layer and the carrier film

15. The adhesive member as set forth in claim 14, wherein a roughness value (Ra) of the primer layer with the surface treatment layer formed thereon is 50 nm or less.

16. The adhesive member as set forth in claim 14, wherein the surface treatment layer is made of a compound including a mercapto group, a disulfide group, or a triazole group.

17. A method of manufacturing a printed circuit board (PCB), the method comprising:
preparing a base substrate;
forming an insulating layer on the base substrate;
forming a primer layer on the insulating layer;
forming a surface treatment layer on the primer layer; and
forming a circuit layer on the surface treatment layer.

18. The method as set forth in claim 17, wherein the forming of the primer layer includes:
preparing a carrier film;
forming an adhesive member by transferring the primer layer onto the carrier film;
disposing the adhesive member such that the primer layer is in contact with the insulating layer;
bonding the insulating layer and the primer layer through a pre-curing process; and
removing the carrier film.

19. The method as set forth in claim 18, further comprising:
performing post-curing process, after the forming of the circuit layer.

20. The method as set forth in claim 17, wherein, in the forming of the primer layer, the primer layer is formed to have a thickness of 0.5% to 5% of the thickness of the insulating layer.

21. The method as set forth in claim 17, wherein a roughness value (Ra) of the primer layer with the surface treatment layer formed thereon is 50 nm or less.
